(19) United States
(12) Patent Application Publication
(10) Pub. No.: US 2007/0173026 A1
(43) Pub. Date: Jul. 26, 2007

(54) Method for fabricating bipolar integrated circuits

(75) Inventors: JinChuan Zeng, Shanghai (CN); Chong Ren, Shanghai (CN); Bin Qiu, Shanghai (CN); Xian-Feng Liu, Shanghai (CN)

Correspondence Address: BIRCH STEWART KOLASCH & BIRCH, PO BOX 747, FALLS CHURCH, VA, 22040-0747, US

(73) Assignee: BCD Semiconductor Manufacturing Limited

(21) Appl. No.: 11/336,899

(22) Filed: Jan. 23, 2006

(51) Int. Cl. H01L 21/331; H01L 21/8222

(52) U.S. Cl. 438/320

(57) ABSTRACT

The present invention discloses a method for fabricating bipolar integrated circuits, wherein LOCOS technology is used to define the active regions needed by all elements so that the self-alignment of the associated layers can be realized, and implant resistor regions are also directly defined in the active regions by local oxide layers; after base regions have been driven in the wafer, the resistors are implanted into the wafer so that the cost of resistor photomasks can be saved; silicon nitride is adopted to be the material of the dielectric layers of the capacitors, and with the characteristic of a buffering oxide etchant that etches oxide faster than it etches silicon nitride, the conventional deposition sequence of the dielectric layer is changed so that the formation of the dielectric layer needs only a single photomask.

### FIELD OF THE INVENTION

The present invention relates to a method for fabricating integrated circuits, particularly to a method for fabricating bipolar integrated circuits, which can realize self-alignment and promote the integration level of circuits.

### BACKGROUND OF THE INVENTION

For the semiconductor industry, the fabrication cost is closely related to the area of the epitaxial layer used in IC fabrication. Therefore, increasing IC integration level and decreasing the use of the epitaxial layer is the target of IC industry.

The conventional method for fabricating bipolar IC comprises the following steps: providing a P-type substrate; forming an N-type buried layer; forming an N-type epitaxial layer; forming deep N⁺ sinkers; forming isolation buried regions; forming base regions; forming emitter regions; forming a contact metal; and forming a protection layer.

To decrease the area occupied by isolations, a P-type buried layer may be formed in the P-type substrate firstly, and next, an N-type extension layer is formed so that the width used to isolate diffusion can be reduced. To increase IC performance, an extrinsic base region may be buried beside the base region. To increase IC design flexibility and IC performance, implant resistors and implant capacitors may also implanted into IC during IC fabrication. Such a high-performance IC needs about 12˜14 photomasks.

In the conventional method for fabricating bipolar IC, the alignment in photolithographic processes usually adopts layer-by-layer alignment or layers-to-one-layer alignment. Sometimes, the alignment may also adopt a complex-mask technology, wherein multiple layers of structures, such as deep N⁺ sinkers, isolations, extrinsic bases, bases, and emitters, are defined in a single photomask so that the alignment error occurring in photolithographic processes can be reduced, and the integration level can be promoted.

The complex-mask technology can realize multi-layer self-alignment and can overcome the problem of alignment error existing in the conventional method for fabricating bipolar IC, and thereby, IC integration level is also effectively promoted.

However, the other elements, such as resistors and capacitors, still need their own photomasks to fabricate, and there are still unavoidable alignment errors occurring. Therefore, tolerance is needed to offset alignment errors. Thus, at present, wafer area has not achieved its best utilization rate yet, and IC integration level has not achieved its maximum either.

### SUMMARY OF THE INVENTION

The primary objective of the present invention is to provide a method for fabricating bipolar integrated circuits, which can promote the integration level of integrated circuits, wherein an LOCOS (Local Oxidation) technology is used to define all the element regions, which are to be formed in the active regions, such as N⁺ sinkers, isolations, extrinsic bases, bases, implant resistors, emitters and capacitors, in order to implement the self-alignment in the succeeding diffusion processes, and thus, the alignment errors resulting from multiple alignment operations of the conventional technology are eliminated. Thereby, the IC fabrication process can be accurately controlled, and the integration level of integrated circuits can be promoted, and the wafer area used by a unitary IC is decreased, and the cost of a unitary IC is also reduced.

Another objective of the present invention is to provide a method for fabricating bipolar integrated circuits, wherein LOCOS is used to define implant resistor regions, and after a drive-in procedure has been performed on base regions, resistors can be implanted in the scale of the entire wafer; thereby, the photomask cost of implanting resistor can be saved, and the alignment errors occurring during the fabrication of those elements is also decreased.

Further objective of the present invention is to provide a method for fabricating bipolar integrated circuits, wherein silicon nitride is used as the material of dielectric layers, and the deposition sequence of the oxide layer and the dielectric layer is changed, and the formation of the dielectric layer needs only one photomask; thus, the photomask cost can be saved, and the alignment errors of those elements can be decreased, and the fabrication cost is reduced.

The method for fabricating bipolar integrated circuits of the present invention comprises the following steps: providing a P-type substrate, and forming an initial oxide layer on the surface of the P-type substrate; sequentially forming an N-type buried layer, an implant resistor buried layer, a capacitor buried layer, a P-type buried layer, an N-type epitaxial layer, and forming an oxide layer on the N-type epitaxial layer; forming a silicon nitride layer on the oxide layer; utilizing a photolithographic procedure to pattern the silicon nitride into the pattern of the active regions needed in the succeeding procedures; performing a thermal oxidation on the oxide layer on the active regions to form local oxidation layers; removing the silicon nitride layer, and utilizing those local oxide layers to define the active regions needed in the succeeding IC fabrication procedures, such as deep N⁺ sinkers, isolations, extrinsic bases, bases, implant resistors, N⁺ emitters and capacitors. The present invention utilizes the local oxide layers to realize the self-alignment of the succeeding multiple diffusion processes, and thus, the alignment errors resulting from multiple alignment operations of the conventional technology is eliminated. Thereby, the IC fabrication process can be accurately controlled, and the integration level of integrated circuits can be promoted.

After the required deep N⁺ sinkers, bases, extrinsic bases and isolations have been formed, P-type implant resistor is implanted to the entire wafer, and then, an emitter ion drive-in procedure is performed to form the required N⁺ emitters. As the local oxide layers have defined the implant resistor regions beforehand, not only none photomask is needed in this procedure, but also the alignment error is decreased. Further, as the dose of the implant resistor is very low in comparison with the dose of the emitter, the dose of the implant resistor will not influence other elements.

Then, a silicon nitride layer is formed on the surface of the oxide layer above the capacitor buried layer to function as the dielectric layer of the metal-insulator-semiconductor capacitor. Next, an oxide deposition procedure is performed on the oxide layer so that the oxide layer can wrap the dielectric layer. Next, an ion drive-in procedure is performed on the abovementioned N⁺ emitters, and the lower electrodes of the capacitors will interconnect owing to the transverse diffusion of the N⁺ sinkers above the capacitor buried layer. As BOE (Buffering Oxide Etchant) etches oxide faster than it etches silicon nitride, BOE is used to etch the oxide layer to form the required contact holes with the silicon-nitride dielectric layer not etched away but only exposed to benefit the succeeding electric connection. The present invention changes the silicon-nitride deposition sequence of the conventional technology and needs not two but only one photomask to form the silicon nitride layer.

Next, a metallic layer is formed on the surface of the oxide layer, and those contact holes enable the metallic layer to electrically connect the underneath elements. Lastly, a protection layer and a pad layer are sequentially formed above the metallic layer. Then, the IC fabrication process according the method for fabricating bipolar integrated circuits of the present invention is completed.

### BRIEF DESCRIPTION OF THE DRAWINGS

FIG. 1 to FIG. 28 are diagrams schematically showing the cross sections of the integrated circuit fabricated according to one embodiment of the present invention.

FIG. 29 to FIG. 31 are diagrams schematically showing the cross sections of the integrated circuit, whose N⁺ sinkers are fabricated according to another embodiment of the present invention.

### DETAILED DESCRIPTION OF THE PREFERRED EMBODIMENTS

The present invention is to be described below in detail in cooperation with the drawings.

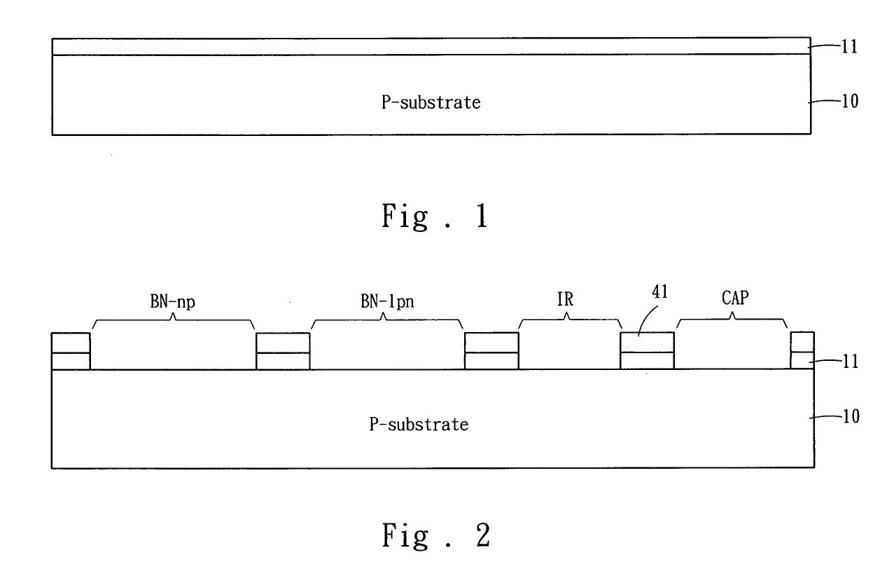

Refer to from FIG. 1 to FIG. 28 diagrams schematically showing the cross sections of the integrated circuit fabricated according to the method of the present invention. As shown in FIG. 1, a P-type substrate 10 is provided firstly, and an initial oxide layer 11 is formed on the surface of the P-type substrate 10. Next, as shown in FIG. 2, via a photolithographic process and a photoresist layer 41, the oxide layer 11 is etched to form BN-np, BN-lnp, IR (Implant Resistor), and CAP (Capacitor) regions of an N-type buried layer, which is needed in the succeeding procedures.

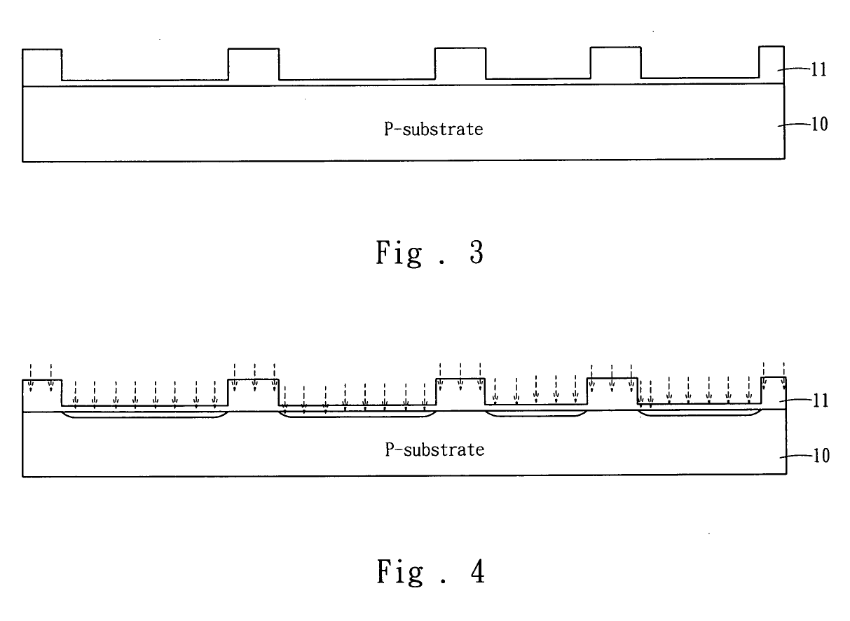

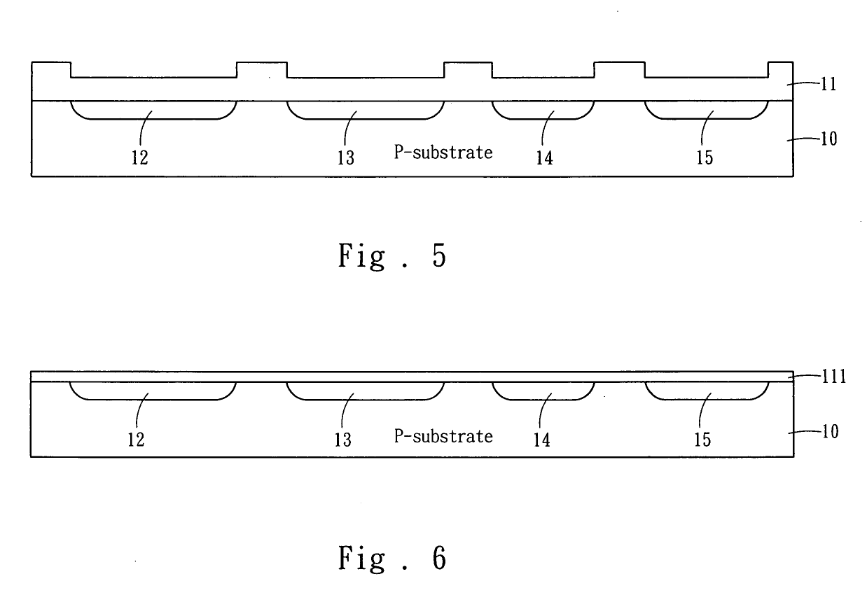

Next, as shown in FIG. 3, the P-type substrate 10 is pre-oxidized with a thermal oxidation process. Then, as shown in FIG. 4, N-type ions, such as Sb⁺ ions, are implanted into the BN-np, BN-lnp, IR, and CAP regions. Next, as shown in FIG. 5, a drive-in process is used to form an N-type NPN-transistor buried layer 12, an N-type LPNP transistor buried layer 13, an IR buried layer 14, and a CAP buried layer 15.

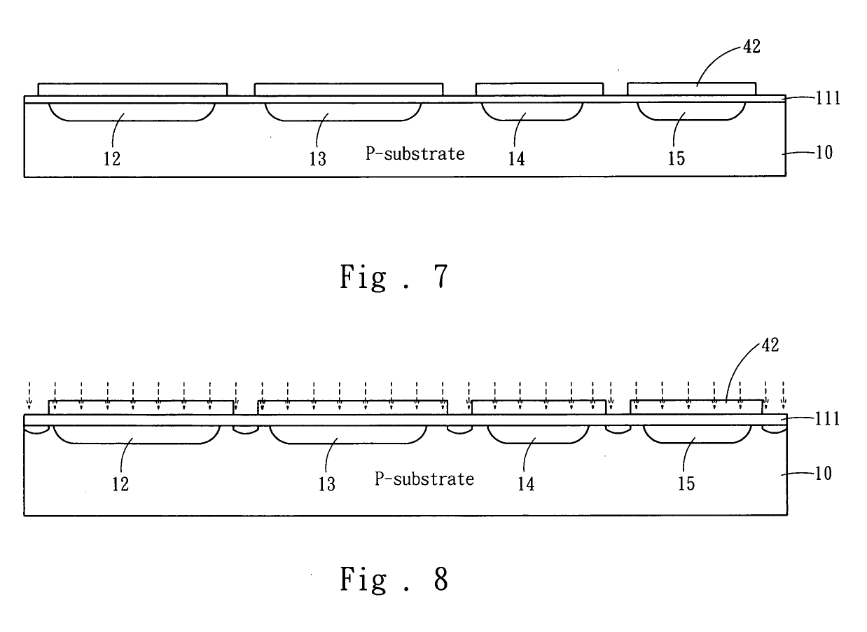

Next, as shown in FIG. 6, the oxide layer 11, which has been polluted by the N-type ions, is removed, and a screen oxide layer 111 is formed via a thermal oxidation process. Next, as shown in FIG. 7, a photolithographic process is used to pattern a photoresist layer 42 to form a pattern shield, which is to be used to form isolation regions. Next, as shown in FIG. 8, P-type ions, such as B⁺ ion, are implanted into the isolation regions formed by the patterned photoresist layer 42. Then, as shown in FIG. 9, a drive-in process is used to form P-type buried layers 31, which surround the N-type buried layers and functions as isolation regions.

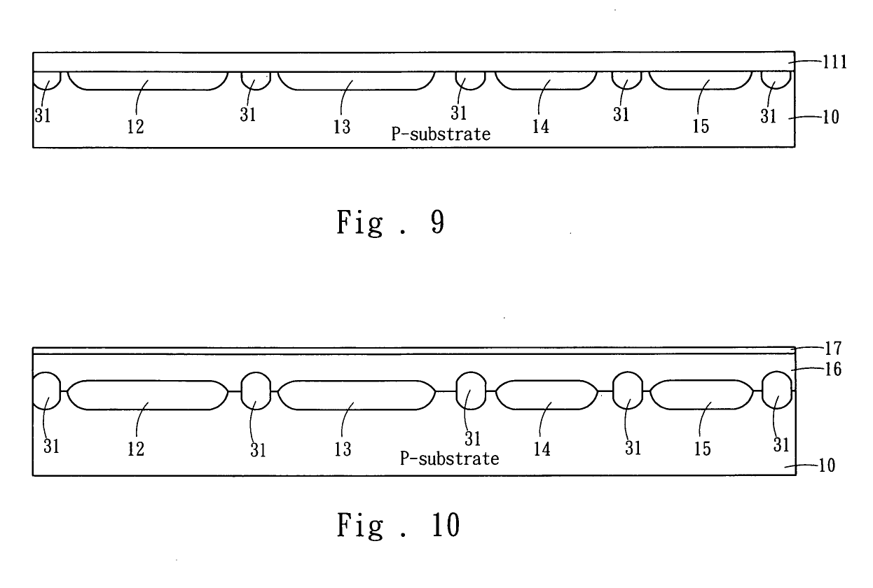

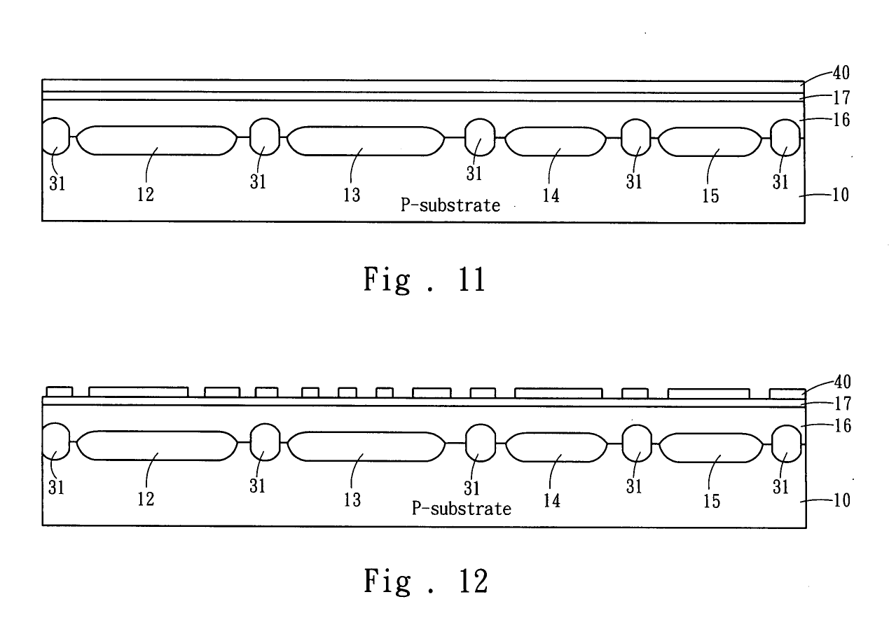

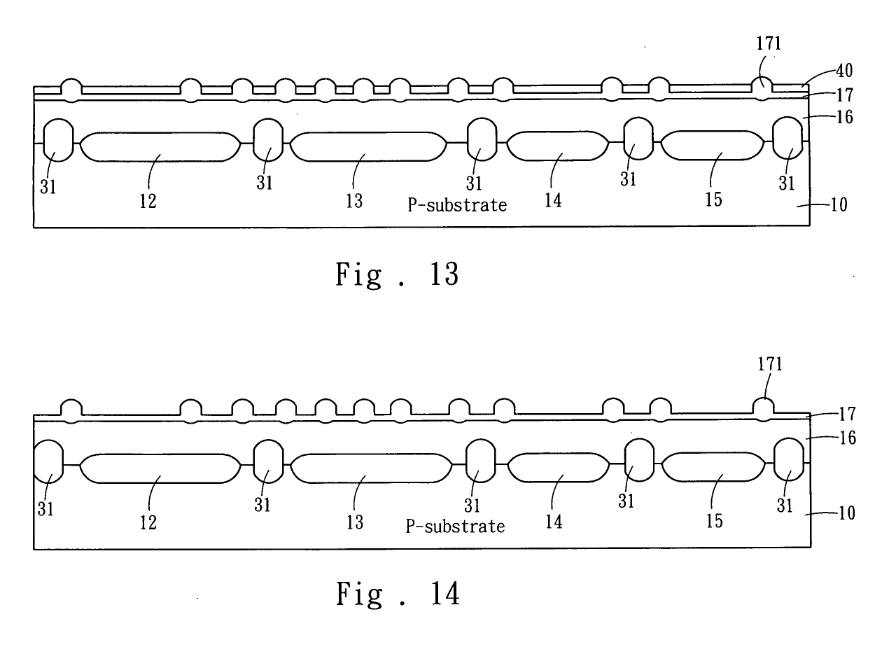

Next, as shown in FIG. 10, the screen oxide layer 111 is removed, and an N-type epitaxial layer 16 is formed on the surface, and then, an oxide layer (SiO₂) 17 is formed on the surface of the N-type epitaxial layer 16. Next, as shown in FIG. 11, a silicon nitride layer (Si₃N₄) 40 is further formed on the surface of the oxide layer (SiO₂) 17. Next, as shown in FIG. 12, a photolithographic process is used to pattern the silicon nitride layer 40 to form active regions, which are needed in the succeeding procedures. Next, as shown in FIG. 13, a thermal oxidation procedure is used to form local oxide layers 171 in the exposed zones of the oxide layer (SiO₂) 17 of the active regions. Next, as shown in FIG. 14, the silicon nitride layer (Si₃N₄) 40 is removed, and the local oxide layers 171 define all the active regions, including: N⁺ sinkers, P⁺ isolations, P⁺ extrinsic bases, P bases, P implant resistors, N⁺ emitters and capacitors, which will be formed in the succeeding procedures, and thereby, the self-alignment of the succeeding procedures is realized.

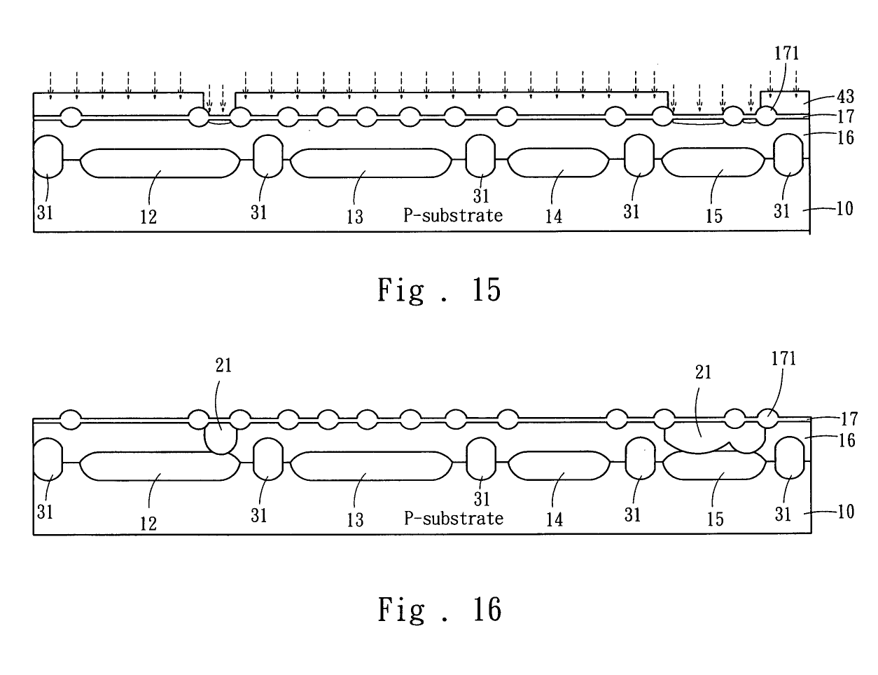

Next, as shown in FIG. 15, a photolithographic process is used to form a photoresist layer 43 on the oxide layer (SiO₂) 17 and the local oxide layers 171 and pattern the photoresist layer 43 to have a pattern needed by N⁺ sinkers; the pattern exposes some portions of the oxide layer (SiO₂) 17 and some portions of the local oxide layers 171 and defines the N⁺ sinker regions, and then, P⁻ ion are implanted into the exposed regions. Next, as shown in FIG. 16, a P⁻ ion drive-in process is used to form the N⁺ sinkers 21.

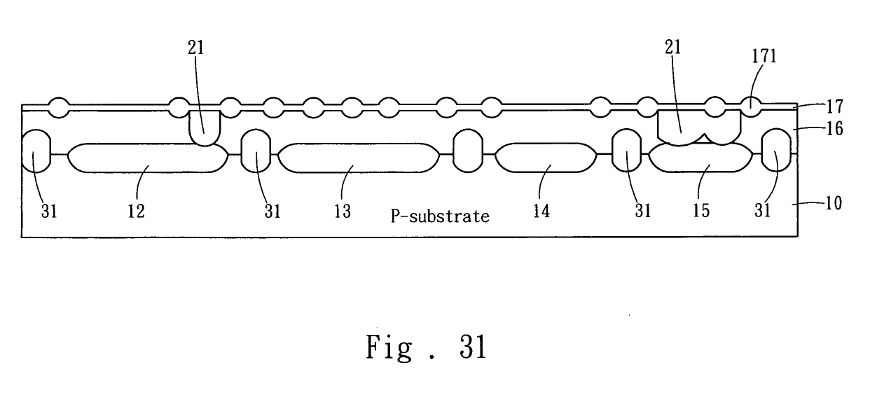

The formation of the N⁺ sinkers 21 and the removal of the silicon nitride layer (Si₃N₄) 40 may also be undertaken in reverse sequence when using phosphorus oxychloride (POCL3) to form N⁺ sinkers. The process is that after the local oxide layers 171 has been formed on the exposed oxide layer (SiO₂) 17 of the active regions via a thermal oxidation process, which has been shown in FIG. 13, the silicon nitride layer (Si₃N₄) 40 is not removed beforehand but is removed together with the oxide layer (SiO₂) 17 via utilizing a pattern of the N⁺ sinker regions defined by a photoresist layer 51 as shown in FIG. 29. Next, as shown in FIG. 30, after the photoresist layer 51 has been removed, phosphorus oxychloride (POCL3) is used to implant P⁺ ions into the N⁺ sinker regions, and then, a drive-in process is used to form the N⁺ sinkers 21. Next, as shown in FIG. 31, the residual silicon nitride layer (Si₃N₄) 40 is also removed.

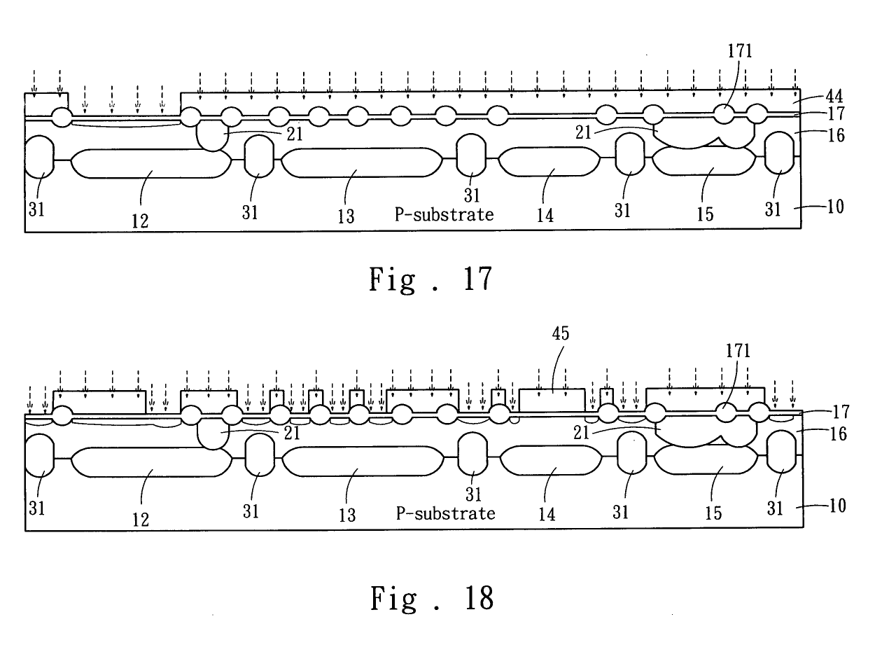

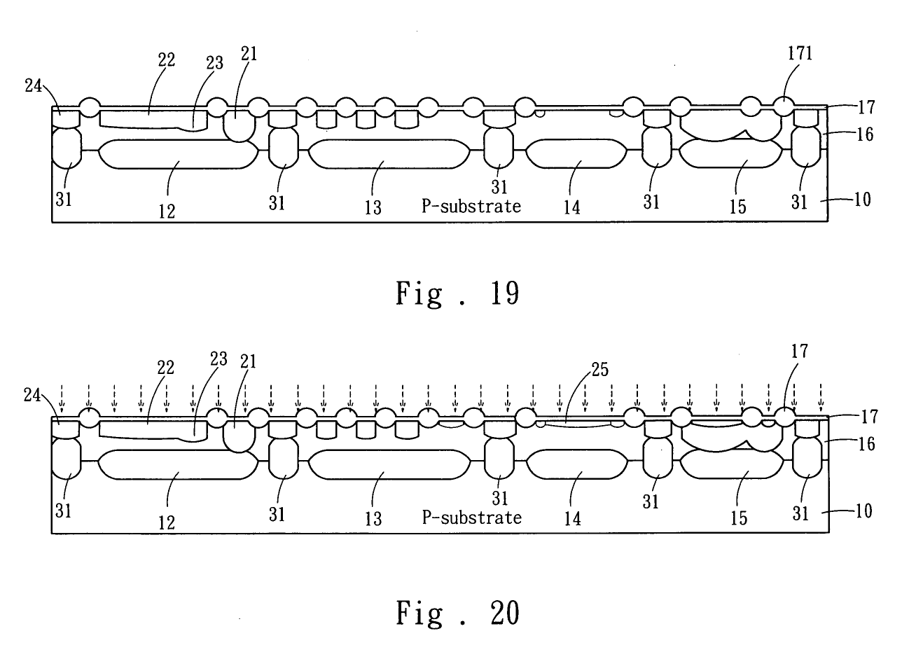

Next, as shown in FIG. 17, a photolithographic process is used to form a photoresist layer 44 on the oxide layer (SiO₂) 17 and the local oxide layers 171 and form a pattern needed by base regions; the pattern exposes some portions of the oxide layer (SiO₂) 17 and some local oxide layers 171, which defines the base regions, and then, B⁺ ions are implanted into the exposed regions. Next, as shown in FIG. 18, the photoresist layer 44 is removed, and a photolithographic process is used to form a photoresist layer 45 on the oxide layer (SiO₂) 17 and the local oxide layers 171 and form a pattern needed by extrinsic base regions; the pattern exposes some portions of the oxide layer (SiO₂) 17 and some local oxide layers 171, which defines extrinsic base regions, and then, B⁺ ions are implanted into the exposed regions. Next, as shown in FIG. 19, a B⁺ ion drive-in process is used to form P bases 22, P⁺ extrinsic bases 23, and P⁺ isolations 24.

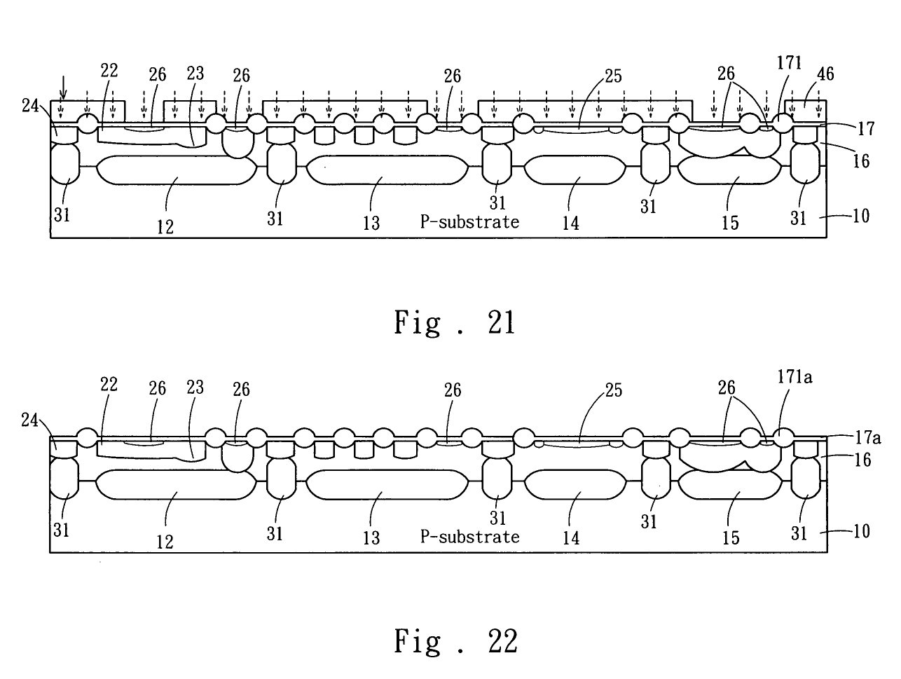

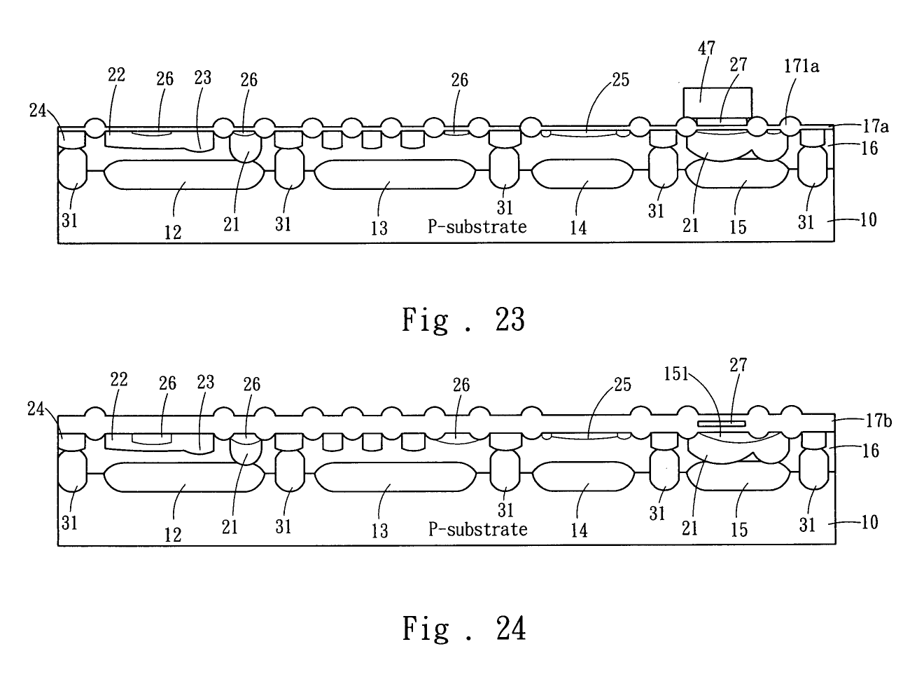

Next, as shown in FIG. 20, after the photoresist layer 45 has been removed, P-type implant resistors 25 are implanted into the oxide layer (SiO₂) 17. Next, as shown in FIG. 21, a photolithographic process is used to form a photoresist layer 46 on the oxide layer (SiO₂) 17 and the local oxide layers 171 and form a pattern needed by N⁺ emitter regions; the pattern exposes some portions of the oxide layer (SiO₂) 17 and some local oxide layers 171, which defines the N⁺ emitter regions, and then, a dopant is implanted into the exposed regions to form N⁺ emitters 26. Next, as shown in FIG. 22, the photoresist layer 46, and the oxide layer (SiO₂) 17 and the local oxide layers 171, which has been polluted by the dopant, are removed; a thermal oxidation process is used to form a new oxide layer (SiO₂) 17a and new local oxide layers 171a. Next, as shown in FIG. 23, a Si₃N₄ dielectric layer 27 is formed on the surface of the oxide layer (SiO₂) 17a above the CAP buried layer 15 by a LPCVD Si₃N₄ deposition and a photoresist layer 47 to defined the CAP remain region and a Si₃N₄ dry etch, and the complex dielectric layer 27 (SiO₂+Si₃N₄) is the medium for the MIS (Metal-Insulator-Semiconductor) capacitor. Next, as shown in FIG. 24, the photoresist layer 47 is removed; an oxide deposition process is performed on the oxide layer (SiO₂) 17a to form an oxide layer 17b, and the oxide layer 17b wraps the dielectric layer 27; an ion drive-in process is performed on those N⁺ emitters 26 to form the required N⁺ emitters 26; the transverse diffusion of the N⁺ sinkers 21 makes the lower electrodes 151 of the MIS capacitors interconnect.

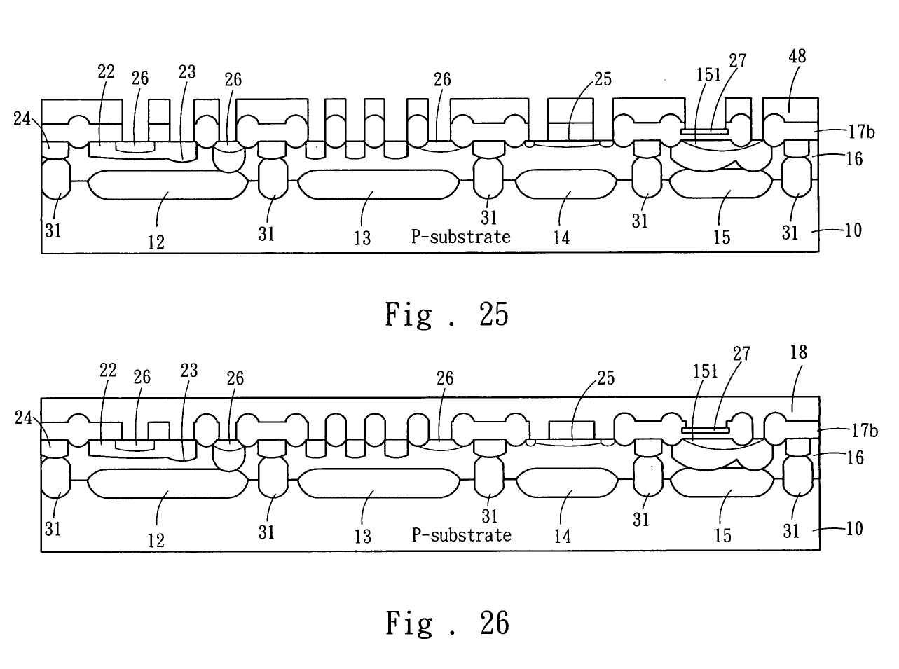

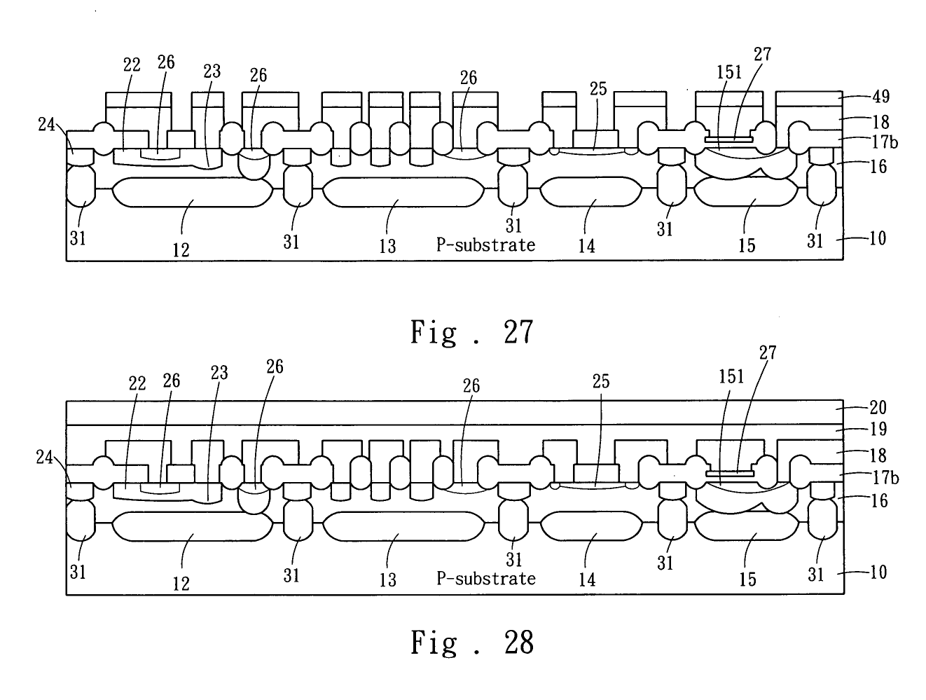

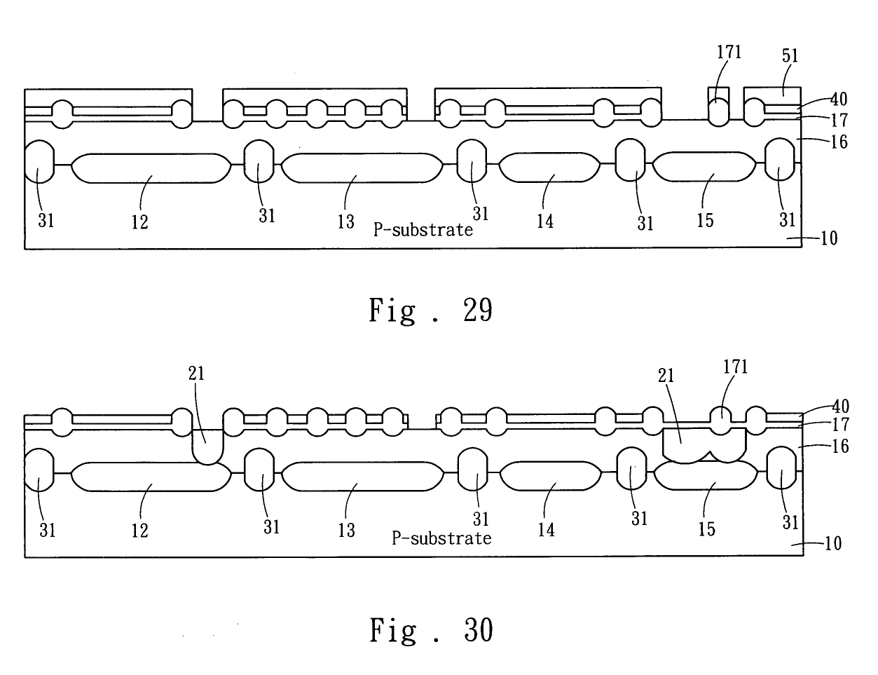

BOE (Buffering Oxide Etchant) etches oxide faster than it etches Si₃N₄. As shown in FIG. 25, via a pattern of a photoresist layer 48, the oxide layer 17b is etched to form multiple contact holes; simultaneously, the Si₃N₄ dielectric layer 27 is not etched away but just exposed to the air owing to the abovementioned characteristic of BOE. Next, as shown in FIG. 26, a first metallic layer 18 is formed on the surface of the oxide layer 17b, and those contact holes enable the first metallic layer 18 to electrically connect those implant resistors 25, N⁺ emitters 26 and dielectric layers 27. Next, as shown in FIG. 27, a photolithographic process is used to form a pattern of a photoresist layer 49, and via the pattern, the first metallic layer 18 is etched to have a pattern required by the integrated circuit. Lastly, as shown in FIG. 28, the photoresist layer 49 is removed, and a protection layer 19 and a pad layer 20 are overlaid above the first metallic layer 18. Thus, the fabrication of the integrated circuit according to the method for fabricating bipolar integrated circuits of the present invention is completed.

In summary, the present invention utilizes the technology of local oxide layers to define all the element regions, which are to be formed in the active regions, to implement the self-alignment in the succeeding diffusion processes, and thus, the alignment errors resulting from multiple alignment operations of the conventional technology is eliminated. Therefore, the IC fabrication process can be accurately controlled, and the integration level of integrated circuits can be promoted, and the wafer area used by a unitary IC is decreased, and the cost of a unitary IC is also reduced. Further, the local oxide layers can also define the implant resistor regions, and after a drive-in process has been performed on the base regions, resistors can be implanted in the scale of the entire wafer; thereby, the photomask cost of implanting resistor of the conventional technology can be saved, and the alignment errors of those elements is also decreased.

Via the characteristic of BOE (Buffering Oxide Etchant) that etches oxide faster than it etches silicon nitride, the present invention changes the silicon-nitride deposition sequence used in the conventional technology and needs only one photomask to form capacitor medium; thus, the photomask cost can be saved, and the alignment errors of those elements can be decreased, and the fabrication cost is reduced.

Those described above are only the preferred embodiments of the present invention, and it is not intended to limit the scope of the present invention. Any equivalent modification and variation according to the spirit of the present invention is to be also included within the scope of the present invention.

What is claimed is:

1. A method for fabricating bipolar integrated circuits, characterized in comprising the following steps:
sequentially forming a buried layer and an N-type epitaxial layer needed by an integrated circuit on a P-type substrate, and forming an oxide layer on said N-type epitaxial layer; and
forming a silicon nitride layer on said oxide layer, and via said silicon nitride layer, which has been patterned, forming a local oxide layer; utilizing said local oxide layer to define active regions, which is needed in the succeeding IC fabrication procedures, to implement the self-alignment needed in the succeeding diffusion processes and to accurately control the IC fabrication process.

2. The method for fabricating bipolar integrated circuits according to claim 1, wherein said active regions include the regions where deep N⁺ sinkers, isolations, extrinsic bases, bases, implant resistors, N⁺ emitters and capacitors are respectively formed.

3. The method for fabricating bipolar integrated circuits according to claim 2, further comprising the following steps:
forming required said deep N⁺ sinkers, said bases, said extrinsic bases, and said isolations; and
implanting said implant resistors into the entire wafer, and driving in emitter ions to form required said N⁺ emitters.

4. The method for fabricating bipolar integrated circuits according to claim 3, wherein the dose of said implant resistor is very small in comparison with the dose of said emitter.

5. The method for fabricating bipolar integrated circuits according to claim 3, further comprising the following steps:
forming a silicon-nitride dielectric layer on the surface of an oxide layer above said capacitor buried layer;
performing an oxide deposition procedure on said oxide layer so that an oxide layer can wrap said dielectric layer;
performing a drive-in procedure on N⁺ ions so that lower electrodes of said capacitors can interconnect via the transverse diffusion of said N⁺ sinkers above said capacitor buried layer;
etching said oxide layer to form required contact holes and to expose said dielectric layer; and
forming a metallic layer on said oxide layer with said metallic layer electrically connecting said dielectric layer via said contact holes to form a metal-insulator-semiconductor capacitor.

6. The method for fabricating bipolar integrated circuits according to claim 5, wherein etching said oxide layer is implemented with a buffering oxide etchant.
